(19) United States
(12) Patent Application Publication
(10) Pub. No.: US 2012/0060366 A1
(43) Pub. Date: Mar. 15, 2012

(54) METHOD FOR DETERMINING WIRING PATHWAY OF WIRING BOARD AND METHOD FOR DETERMINING WIRING PATHWAY OF SEMICONDUCTOR DEVICE

(75) Inventor: Mikio NAKANO, Kawasaki-shi (JP)

(73) Assignee: KABUSHIKI KAISHA TOSHIBA, Tokyo (JP)

(21) Appl. No.: 13/029,972

(22) Filed: Feb. 17, 2011

(30) Foreign Application Priority Data
Sep. 15, 2010 (JP) 2010-207073

(51) Int. Cl. H05K 3/02; H05K 3/10

(52) U.S. Cl. 29/847; 29/846

(57) ABSTRACT

In an embodiment of the invention, a wiring pathway determining method includes: tracing continuously a first wiring forming grid to extend an additional wiring line from a starting point to one first already-selected intersection selected from plural first intersections; computing a first via allocatable region where an additional via can be allocated on a first wiring layer and a second via allocatable region where the additional via can be allocated on a second wiring layer based on positions of an already-designed wiring line and an already-designed via; allocating the additional via, in which a first already-selected intersection is included in an arbitrary position in a region of a lower surface, such that the lower surface is included in the first via allocatable region and such that an upper surface is included in a second via allocatable region; and tracing continuously a second wiring forming grid to extend the additional wiring line from the additional via to an ending point.

### CROSS-REFERENCE TO RELATED APPLICATION

This application is based upon and claims the benefit of priority from prior Japanese Patent Application No. 2010-207073, filed on Sep. 15, 2010, the entire contents of which are incorporated herein by reference.

### FIELD

Embodiments of the present invention relate to a method for determining a wiring pathway of a wiring board and a method for determining a wiring pathway of a semiconductor device.

### BACKGROUND

There are various wiring boards such as a wiring board for a semiconductor package such as a Ball Grid Array (BGA) package, printed circuit boards (PCB) for various electric instruments, and a wiring layer for a semiconductor integrated circuit.

A maze method is well known as a method for determining a wiring pathway of the wiring board. In the maze method, grids is virtually set on the wiring board to which the wiring is performed, and a starting point and an ending point of the wiring are set on the wiring board. A wiring pathway is fixed on the grids so as to connect the starting point and the ending point. Even if an obstacle such as another wiring lines and vias exists in a plane to which the wiring is performed, a pathway for the wiring can be found while the obstacle is sidestepped. Therefore, the maze method is widely used.

### BRIEF DESCRIPTION OF THE DRAWINGS

FIG. 1 is a view for explaining an exemplary embodiment of the invention (part 1);

FIG. 2 is a view for explaining an embodiment (part 2);

FIG. 3 is a view for explaining an embodiment (part 3);

FIG. 4 is a flowchart illustrating a wiring pathway determining method of an embodiment;

FIG. 5 is a view for explaining an embodiment (part 4);

FIG. 6 is a view for explaining an embodiment (part 5);

FIG. 7 is a view for explaining an embodiment (part 6);

FIG. 8 is a view for explaining a first embodiment of the invention (part 1);

FIG. 9 is a view for explaining a first embodiment (part 2);

FIG. 10 is a view for explaining a first embodiment (part 3);

FIG. 11 is a flowchart illustrating a wiring pathway determining method of the first embodiment;

FIG. 12 is a block diagram illustrating a wiring design apparatus of the first embodiment;

FIG. 13 is a view for explaining a second embodiment of the invention;

FIG. 14 is a flowchart illustrating a wiring pathway determining method of the second embodiment;

FIG. 15 is a block diagram illustrating a wiring design apparatus of the second embodiment;

FIG. 16 is a view for explaining a third embodiment of the invention;

FIG. 17 is a flowchart illustrating a wiring pathway determining method of the third embodiment;

FIG. 18 is a flowchart illustrating a wiring pathway determining method according to a fourth embodiment of the invention;

FIG. 19 is a block diagram illustrating a wiring design apparatus of the fourth embodiment;

FIG. 20 is a view for explaining a fifth embodiment of the invention;

FIG. 21 is a flowchart illustrating a wiring pathway determining method of the fifth embodiment; and

FIG. 22 is a block diagram illustrating a wiring design apparatus of the fifth embodiment.

### DETAILED DESCRIPTION

In one embodiment of the present invention, a wiring pathway determining method includes: providing a first wiring layer and a second wiring layer in a wiring board; assigning a first wiring forming grid to the first wiring layer, the first wiring forming grid including plural first horizontal lines, plural first vertical lines, and plural first intersections that are of intersections of the plural first horizontal lines and the plural first vertical lines; assigning a second wiring forming grid to the second wiring layer, the second wiring forming grid including plural second horizontal lines, plural second vertical lines, and plural second intersections that are of intersections of the plural second horizontal lines and the plural second vertical lines; assigning a first already-designed wiring line to the first wiring layer, the first already-designed wiring line being formed by continuously tracing the first wiring forming grid; assigning a second already-designed wiring line to the second wiring layer, the second already-designed wiring line being formed by continuously tracing the second wiring forming grid; assigning commonly an already-designed via to the first wiring layer and the second wiring layer, the already-designed via establishing electric conduction between the first already-designed wiring line and the second already-designed wiring line; assigning an already-designed wiring line from the first wiring layer to the second wiring layer, the already-designed wiring line establishing electric conduction between the first already-designed wiring line and the second already-designed wiring line through the already-designed via; determining a starting point on the first wiring forming grid and an ending point on the second wiring forming grid; and determining a pathway of an additional wiring line having a predetermined width based on a pathway cost corresponding to the pathway, the additional wiring line establishing electric conduction from the starting point to the ending point through a columnar additional via including an upper surface and a lower surface, the upper surface and the lower surface having a predetermined dimension. Determining the pathway of the additional wiring line includes: tracing continuously the first wiring forming grid to extend the additional wiring line from the starting point to one first already-selected intersection selected from the plural first intersections; computing a first via allocatable region and a second via allocatable region based on positions of the already-designed wiring line and the already-designed via, the additional via being able to be allocated on the first wiring layer in the first via allocatable region, the additional via being able to be allocated on the second wiring layer in the second via allocatable region; allocating the additional via, in which the first already-selected intersection is included in an arbitrary position in a region of the lower surface, such that the lower surface is included in the first via allocatable region and such that the upper surface is included in the second via allocatable region; and tracing continuously the second wiring forming grid to extend the additional wiring line from the additional via to the ending point.

Although embodiments are described below with reference to the drawings, the invention is not limited to the embodiments. In the following drawings, a common constituent is designated by a common reference numeral.

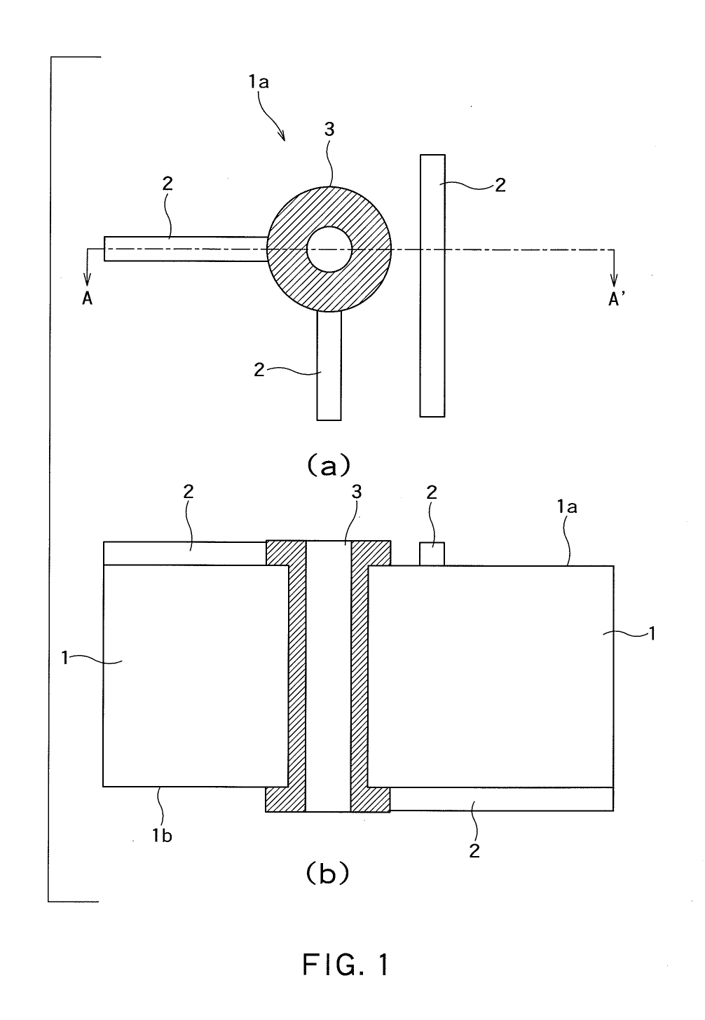

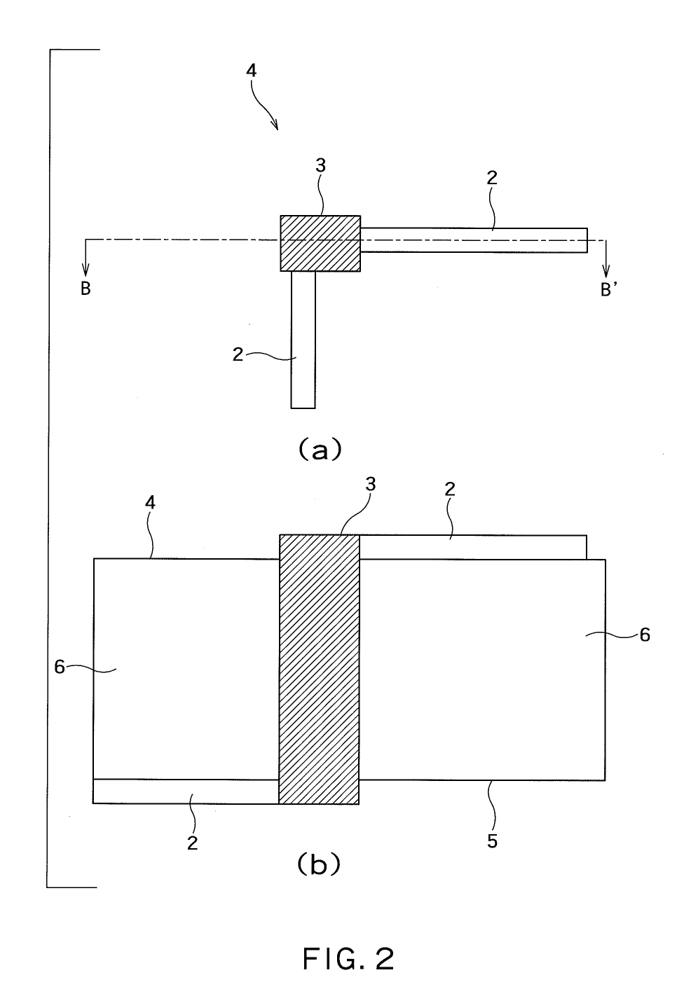

Before the description of the embodiments, a wiring board that becomes a design target will briefly be described with reference to FIGS. 1 and 2. In the invention, the wiring board that becomes the design target is not limited to the wiring board described below.

FIG. 1 illustrates part of the wiring board of a semiconductor package such as the BGA package or a wiring board such as PCBs of various electric instruments. Specifically, FIG. 1 (a) is a plan view of part of the wiring board when viewed from a side of a wiring board upper surface 1a, and FIG. 1 (b) is a sectional view taken along a line A-A′ of FIG. 1 (a).

As illustrated in FIG. 1 (a), wiring lines 2 are provided on the wiring board upper surface (wiring layer) 1a of a wiring board 1, and a via 3 having a circular upper surface is also provided on the wiring board upper surface 1a. A direction (wiring direction) in which the wiring lines 2 can extend on the wiring board 1 (specifically, wiring board upper surface 1a and wiring board lower surface 1b) is fixed to plural predetermined directions. For example, the wiring direction is fixed to an X-direction (horizontal direction), a Y-direction (vertical direction), and an oblique-45-degree direction. As illustrated in FIG. 1 (b), the via 3 pierces the wiring board 1 from the wiring board upper surface (wiring layer) 1a to the wiring board lower surface (wiring layer) 1b, and the via 3 electrically connects the wiring line 2 on the wiring board upper surface 1a and the wiring line 2 on the wiring board lower surface 1b. In FIG. 1, the wiring lines 2 can be allocated on the two layers, that is, the wiring board upper surface 1a and the wiring board lower surface 1b. However, the number of layers in which the wiring lines 2 can be allocated is not limited to two, but it is necessary to allocate the wiring lines 2 in at least two layers. That is, the wiring board 1 that becomes the design target includes at least two layers in which the wiring lines 2 can be allocated and at least one via 3. The shapes of the upper surface and lower surface of the columnar via 3 are not limited to the circular shape illustrated in FIG. 1 (a).

FIG. 2 illustrates part of a wiring layer of a semiconductor integrated circuit. Specifically, FIG. 2 (a) is a plan view of part of the wiring layer, and FIG. 2 (b) is a sectional view taken along a line B-B′ of FIG. 2 (a). As illustrated in FIG. 2 (a), the wiring lines 2 and the via 3 are provided on a first wiring layer 4 of a semiconductor integrated circuit board 6. The direction (wiring direction) in which the wiring lines 2 can extend on each wiring layer is fixed to plural predetermined directions. For example, the wiring direction is fixed to the X-direction (horizontal direction), the Y-direction (vertical direction), and the oblique-45-degree direction. Unlike the via 3 illustrated in FIG. 1 (a), the via 3 illustrated in FIG. 2 (a) has the rectangular upper surface and lower surface. As illustrated in FIG. 2 (b), the via 3 pierces the semiconductor integrated circuit board 6 from the first wiring layer 4 to a second wiring layer 5, and the via 3 electrically connects the wiring line 2 on the first wiring layer 4 and the wiring line 2 on the second wiring layer 5. In FIG. 2, the wiring lines 2 can be allocated on the two layers, that is, the first wiring layer 4 and the second wiring layer 5. However, the number of layers in which the wiring lines 2 can be allocated is not limited to two, but it is necessary to allocate the wiring lines 2 in at least two layers. That is, the semiconductor integrated circuit board 6 that becomes the design target includes at least two layers in which the wiring lines 2 can be allocated and at least one via. The shapes of the upper surface and lower surface of the columnar via 3 are not limited to the rectangular shape illustrated in FIG. 2 (a).

In the wiring board 1 illustrated in FIG. 1, usually diameters of the upper surface and lower surface of the via 3 are larger than a width of the wiring line 2. The via 3 such as a double-cut via having the upper surface and lower surface whose widths are larger than the width of the wiring lines also exist in the semiconductor integrated circuit board 6 illustrated in FIG. 2. The width of each wiring line 2 and dimensions of the via 3 are previously fixed in the wiring board 1 and the semiconductor integrated circuit board 6.

How the inventor makes the embodiments of the present invention will be described below.

The inventor makes a wiring design on the wiring board. In such cases, the inventor adopts the maze method as one of the method for making the wiring design on the wiring board. The maze method will be described in detail as an example of the wiring design method.

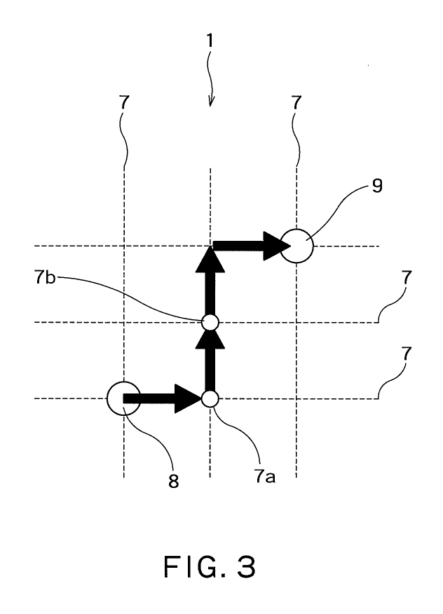

As illustrated in FIG. 3, in the maze method, grids (wiring forming grids) 7 are virtually set on the wiring board 1 to which the wiring is performed. The wiring lines 2 are provided on the grids 7. Accordingly, the grids 7 are set according to a predetermined wiring pitch and the direction (wiring direction) in which the wiring lines 2 can extend on the wiring board 1. At this point, it is assumed that the wiring direction is the X-direction (horizontal direction) and the Y-direction (vertical direction). A starting point 8 and an ending point 9 of the wiring line 2 are set on the wiring board 1.

As illustrated in FIG. 3, the pathway of the wiring line 2 from the starting point 8 to the ending point 9 is searched (wiring pathway is found). That is, the wiring line 2 proceeds by finding the grid 7, to which the wiring is performed because the obstacle such as another wiring lines 2 and the vias 3 does not exist. At this point, a cost called a search cost is computed every time the wiring line 2 proceeds from one grid 7 to an adjacent grid 7. The search cost is added every time the wiring line 2 proceeds from one grid 7 to an adjacent grid 7, thereby computing an accumulated cost (pathway cost) that is of the sum of the search costs. At this point, it is assumed that the search cost of “1” is added every time the wiring line 2 proceeds from one grid 7 to an adjacent grid 7. For example, as illustrated in FIG. 3, when the wiring line 2 proceeds from the starting point 8 to an intersection 7a of the grids 7 by one, the accumulated cost becomes “1” because the search cost of “1” is added. Then, when the wiring line 2 proceeds from the intersection 7a to an intersection 7b of the grids 7 by one, the accumulated cost becomes 1+1=2 because the search cost of “1” is added. Thus, the search of the pathway for the wiring line 2 and the computation of the accumulated cost are repeated. The pathway in which the accumulated cost becomes the minimum is determined as the wiring pathway in the pathways of the wiring line 2 from the starting point 8 to the ending point 9.

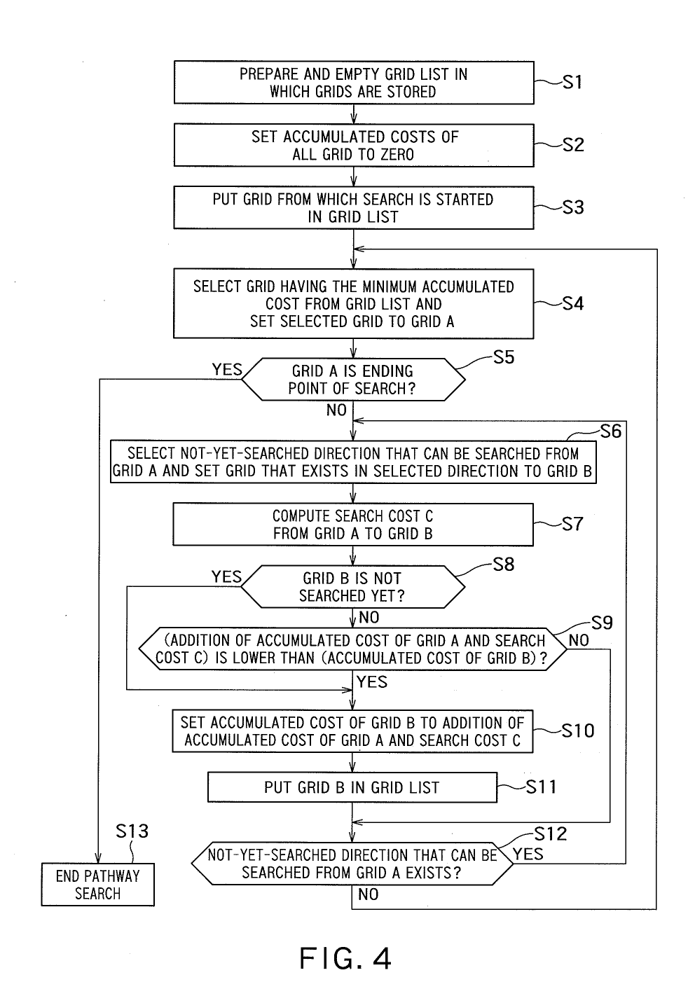

More specifically, the wiring is performed according to a flowchart illustrated in FIG. 4. The wiring method includes 13 steps. Each step will be described below.

(Step 1) A grid list in which the grids are stored is prepared and emptied.

(Step 2) The accumulated costs of all the grids are set to 0.

(Step 3) The grid in which the search is started is put in the grid list.

(Step 4) The grid whose accumulated cost becomes the minimum is selected from the grid list and set to a grid A.

(Step 5) A determination whether the grid A is the ending point of the search is made.

(Step 6) A not-yet-searched direction that can be searched is selected from the grid A. A grid that exists in the selected direction is set to a grid B.

(Step 7) A search cost C from the grid A to the grid B is computed.

(Step 8) A determination whether the grid B is not searched yet is made.

(Step 9) A determination whether (addition of the accumulated cost to the grid A and the search cost C) is lower than (the already-searched accumulated cost) is made.

(Step 10) The accumulated cost to the grid B is set to the sum of the accumulated cost to the grid A and the search cost C.

(Step 11) The grid B is put in the grid list.

(Step 12) A determination whether a not-yet-searched direction that can be searched from the grid A exists is made.

(Step 13) The search of the pathway is ended.

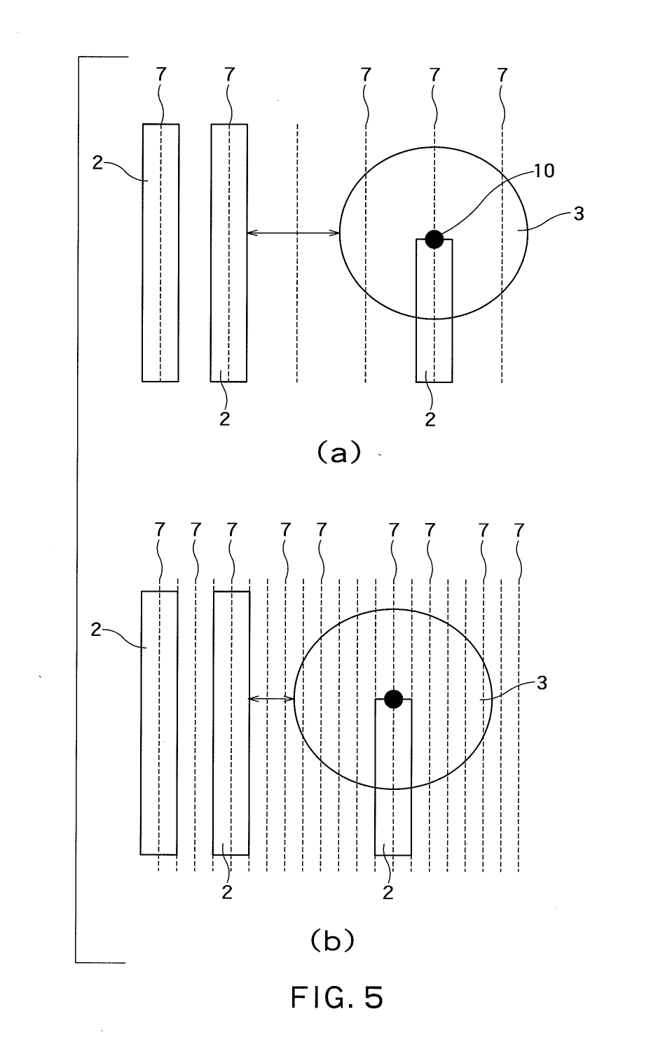

As described above, in making the wiring design by the maze method, an interval between the grids 7 is set based on the predetermined wiring pitch, in other words, a minimum spacing between the wiring lines 2 adjacent to each other. FIG. 5 (a) is a plan view illustrating an allocation relationship among the wiring lines 2, the grids 7, and the via 3. In FIG. 5 (a), the via 3 is allocated such that a center point 10 of the via 3 is located in the center in an end portion of the wiring line 2 connected to the via 3 and such that the center point 10 overlaps a central point at a wiring end located on the grid 7. In making the wiring design in the setting of FIG. 5 (a), sometimes the interval between the via 3 and the wiring line 2 adjacent to the via 3 is excessively increased when the diameter of the via 3 is larger than the width of the wiring lines 2. The excessively-increased interval means that a region where the wiring lines 2 can be routed on the wiring layer is uselessly consumed. Accordingly, a routability is significantly degraded for the subsequent wiring lines 2. As used herein, the routability means a degree of freedom in which the wiring lines 2 are routed.

In order to solve the problem, it is considered that the interval between the grids 7 is decreased to narrow the interval between the wiring line 2 and the via 3 as illustrated in FIG. 5 (b). However, because a processing time of the wiring design and a memory capacity necessary for the wiring design are reversely proportional to the square of the interval between the grids 7, the method for decreasing the interval between the grids 7 causes a problem in that the processing time and the necessary memory capacity are dramatically increased, in other words, the design time and the consumption of the computer resource are increased.

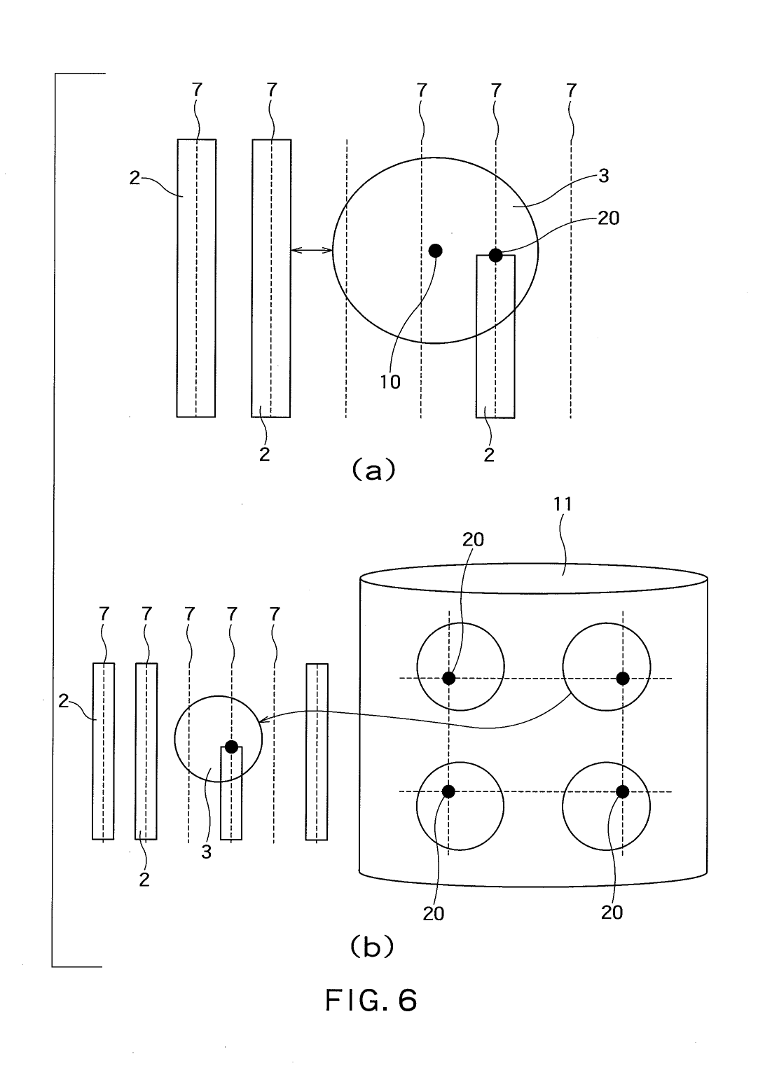

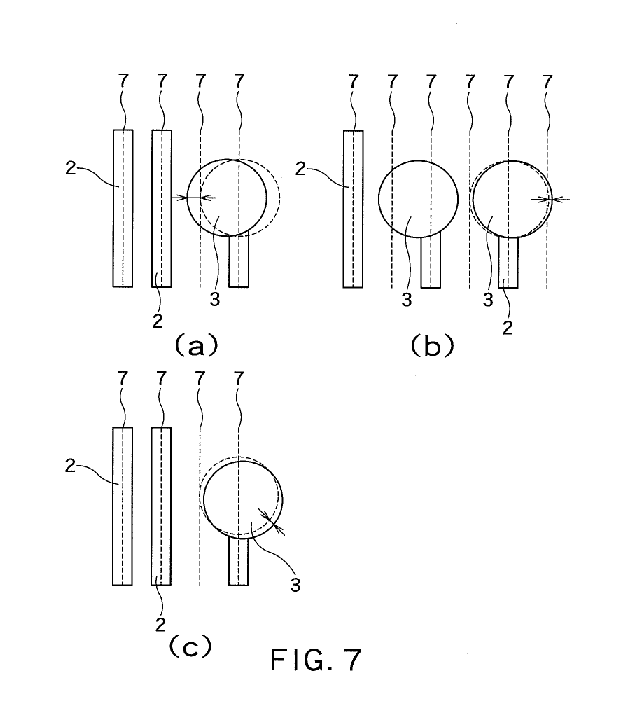

As illustrated in FIG. 6 (a), a method for allocating the via 3 in an off-grid position, in other words, a method for allocating the via 3 without restricting to the allocation in which the center point 10 of the via 3 overlaps a central point 20 at the wiring end is also considered as another approach to the problem. Specifically, in order to allocate the via 3 in the off-grid position, a library 11 including pieces of positional information on the plural vias 3 whose center points 10 (not illustrated) are shifted from the central point 20 at the wiring end as illustrated in FIG. 6 (b) is prepared, and the via 3 located in the optimum position is selected from the plural vias 3. However, how much the center point 10 of the via 3 is shifted depends on the situation, and it is difficult to prepare the library 11 that can respond to any case (FIG. 7 illustrates some examples in which the center points 10 of the vias 3 are shifted, and it is necessary that the library 11 include a huge number of examples).

Therefore, in order to solve the problem, the inventor devises a new way to determine the optimum position of the vias 3 irrespective of the grids 7 in the method for designing the wiring of the wiring board and the semiconductor integrated circuit. That is, the optimum via position is computed from the surrounding situations such as the positions of the already-allocated wiring lines 2 and vias 3, and the vias 3 are allocated in the computed position, thereby making the wiring design. According to the wiring method, the routability can be improved while the design time and the consumption of the computer resource are suppressed.

Embodiment of the invention will be described below.

### First Embodiment

In a first embodiment of the invention, the optimum position of the vias 3 is determined irrespective of the wiring grids 7. Specifically, in the positional relationship between the already-allocated wiring lines 2 and vias 3 (already-designed wiring lines and already-designed vias), a position where the number of DRC errors generated by allocating the vias 3 therein becomes the minimum is determined as the position of the vias 3.

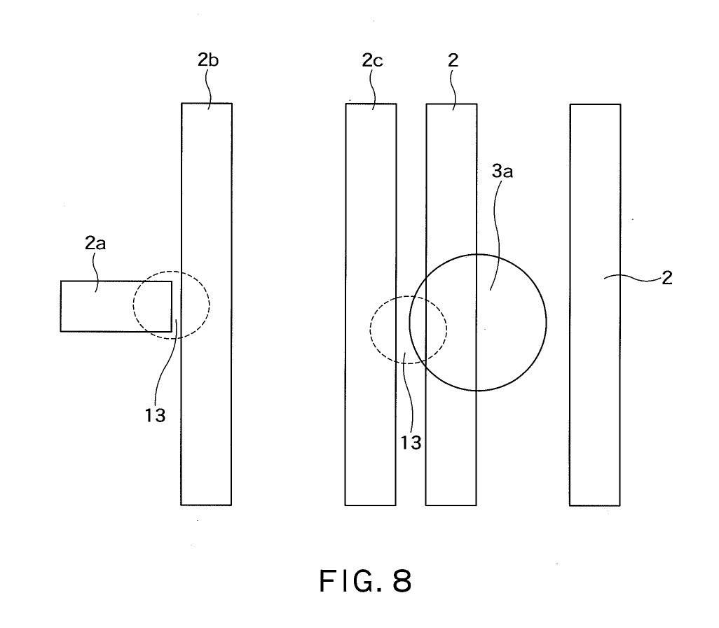

As used herein, the DRC error means an error that is obtained by performing a Design Rule Check (DRC) to the wired wiring board 1. Specifically, a check whether the design is performed according to a rule called a design rule to which each wiring line 2 and each via 3 should conform is made, and a point at which the design is not performed according to the design rule is referred to as the DRC error (design rule violation). For example, as illustrated in FIG. 8, when an interval between a wiring line 2a and a wiring line 2b and an interval between a wiring line 2c and a via 3a are lower than a predetermined value, the intervals are detected as a point (DRC error) 13 that violates the design rule.

In the first embodiment, the maze method is used as the wiring design method. In the first embodiment, the wiring design method is not limited to the maze method, but another method may be used as the wiring design method. In the first embodiment, the wiring is performed on the wiring board 1 of the semiconductor package such as the BGA package. However, in the first embodiment, the wiring board that becomes the design target is not limited to the wiring board 1 of the semiconductor package.

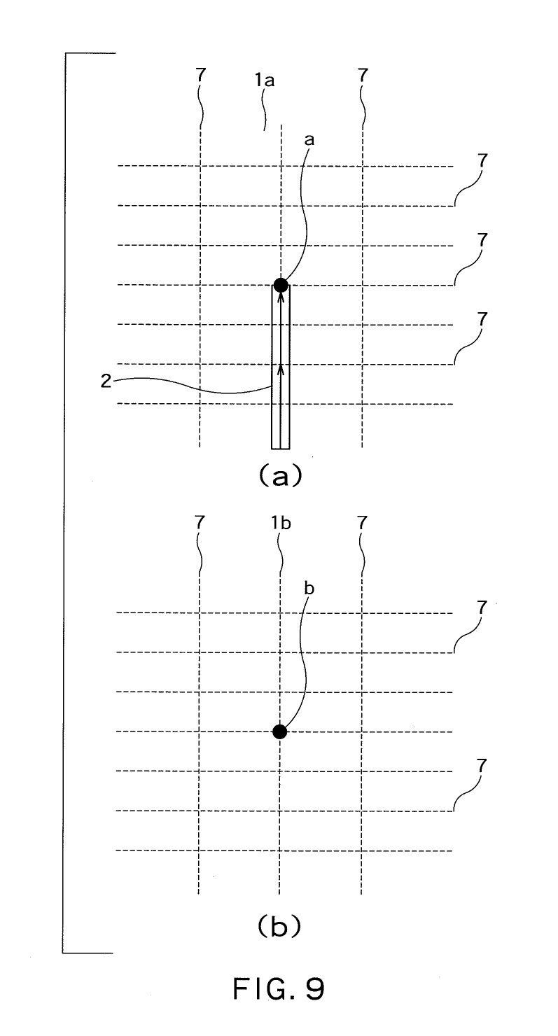

FIG. 9 illustrates a process of searching the pathway of the wiring line 2 on the wiring board 1 by the maze method. The search progresses from a central point (the first already-selected intersection) a at the wiring end of the wiring line 2 extending along the grids 7 on the wiring board upper surface 1a illustrated in FIG. 9 (a) to a point b on the wiring board lower surface 1b illustrated in FIG. 9 (b). The point b overlaps the central point a at the wiring end in a three-dimensional manner.

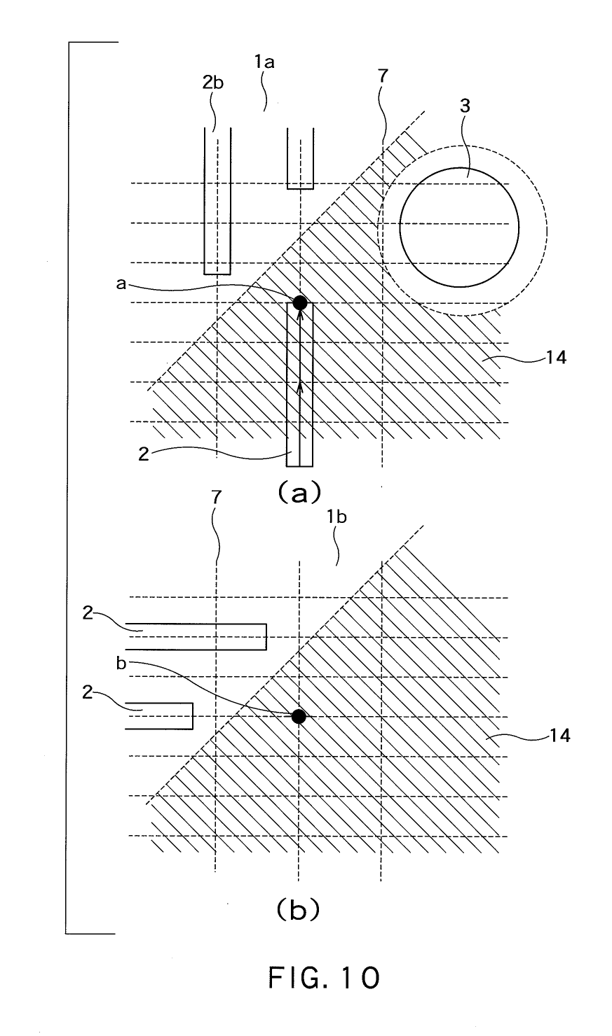

At this point, in the first embodiment, the wiring is performed as illustrated in an example of FIG. 10. That is, a region (via allocatable region) 14 where the number of DRC errors 13 generated by allocating the new via 3 becomes the minimum is found in the positional relationship between the already-allocated wiring lines 2 and vias 3 (already-designed wiring lines and already-designed vias). The via 3 is allocated in the region 14 such that the central point a at the wiring end and the point b are included in the regions of the upper surface and lower surface of the via 3. For example, in the example of FIG. 10, because the DRC error 13 is not generated (the number of generated DRC errors 13=0) in the region 14 illustrated by diagonal lines, an arbitrary position in the region 14 is determined as the position of the via 3.

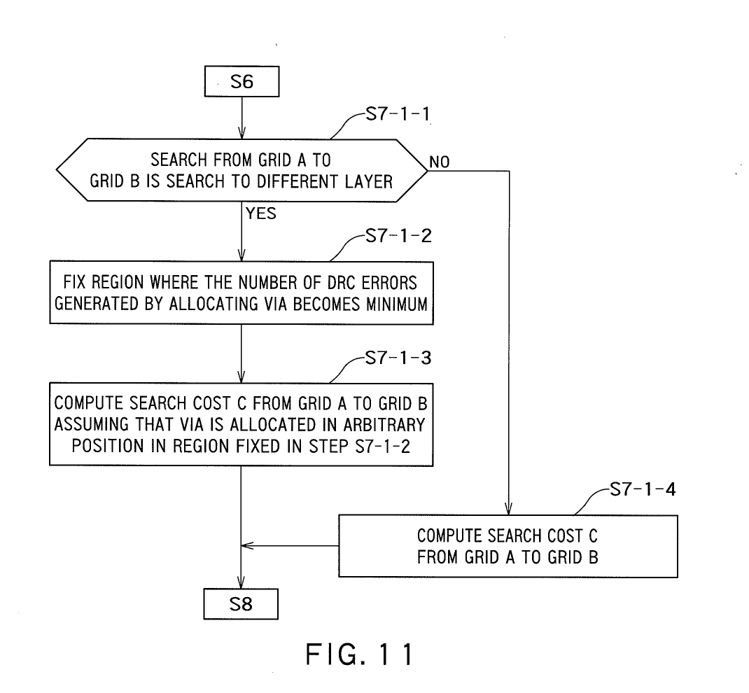

A flowchart of the wiring method of the first embodiment is similar to that of FIG. 4, and Step S7 in the flowchart of FIG. 4 is replaced with a flowchart of FIG. 11.

The flowchart of FIG. 11 unique to the first embodiment will be described in detail. In the first embodiment, the following steps are performed after Step S6 of FIG. 4.

(Step 7-1-1) A determination whether the search from the grid A to the grid B is the search to the different wiring layer is made.

(Step 7-1-2) The region where the number of DRC errors generated by allocating the via becomes the minimum is fixed.

(Step 7-1-3) Assuming that the via is allocated in an arbitrary position in the region fixed in Step 7-1-2, the search cost C from the grid A to the grid B is computed.

(Step 7-1-4) The search cost C from the grid A to the grid B is computed.

Then the flow goes to Step S8.

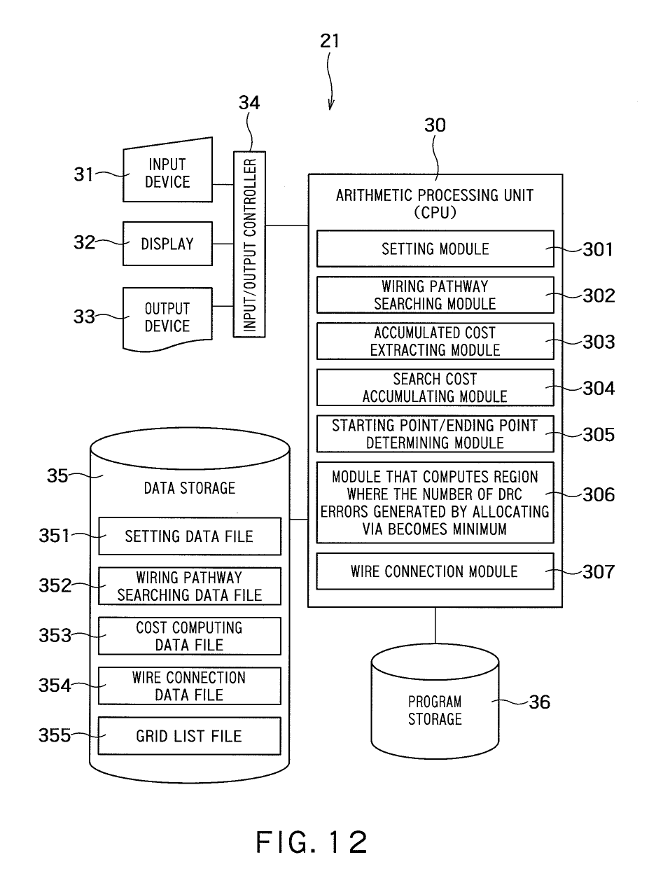

FIG. 12 is a block diagram illustrating a wiring design apparatus 21 of the first embodiment. As illustrated in FIG. 12, the wiring design apparatus 21 of the first embodiment includes an input device 31 to which input data is input, an arithmetic processing unit (CPU) 30 that makes the wiring design, a display 32 that displays design result, an output device 33 that outputs the design result, a program storage 36 in which a wiring design program is stored, and a data storage 35 in which various pieces of data relating to the wiring design are stored. The input device 31, the display 32, and the output device 33 are connected to the arithmetic processing unit 30 through an input/output controller 34. The program storage 36 and the data storage 35 are directly connected to the arithmetic processing unit 30. The arithmetic processing unit 30 includes a setting module 301, a wiring pathway searching module 302, an accumulated cost extracting module 303, a search cost accumulating module 304, a starting point/ending point determining module 305, a module 306 that computes the region where the number of DRC errors generated by allocating the via becomes the minimum, and a wire connection module 307. The data storage 35 includes a setting data file 351, a wiring pathway searching data file 352, a cost computing data file 353, a wire connection data file 354, and a grid list file 355. The wiring method is performed with the wiring design apparatus 21 illustrated in FIG. 12.

According to the first embodiment, the vias 3 can be allocated in the optimum position without restricting to the grid position. Therefore, the region where the wiring lines 2 can be routed on the wiring layer is not uselessly consumed, but the routability can be improved. Particularly, the routability can be improved when the dimension of the vias 3 is larger than the wiring width of the wring lines 2. Additionally, the wiring grid interval is set equal to that of the conventional method, so that the design time and the consumption of the computer resource can be suppressed.

In the first embodiment, the wiring method is adopted for the wiring board 1 including the two wiring layers (wiring board upper surface 1a and wiring board lower surface 1b) in which the wiring lines 2 can be allocated. However, some embodiments of the invention is not limited to the two wiring layer, but some embodiments of the invention may be applied to at least three wiring layers. In such cases, in consideration of the plural wiring layers connected to the via 3, the position of the via 3 is determined in the region where the number of DRC errors becomes the minimum.

### (Modification of First Embodiment)

In the first embodiment, the wiring is performed in the wiring board of the semiconductor package such as the BGA package. However, the first embodiment can also be applied to the wiring layer of the semiconductor integrated circuit illustrated in FIG. 2. In a modification of first embodiment, because the wiring method and the wiring design apparatus are identical to those of the first embodiment, the descriptions are not repeated here (see FIGS. 4 and 10 to 12). According to the modification, the vias 3 are allocated in the optimum position without restricting the grid position. Therefore, the region where the wiring lines 2 can be routed on the wiring layer is not uselessly consumed, but the routability can be improved. Particularly, the routability can be improved when the dimension of the vias 3 such as the double-cut via is larger than the width of the wiring lines 2. Additionally, the wiring grid interval is set equal to that of the conventional method, so that the design time and the consumption of the computer resource can be suppressed.

### Second Embodiment

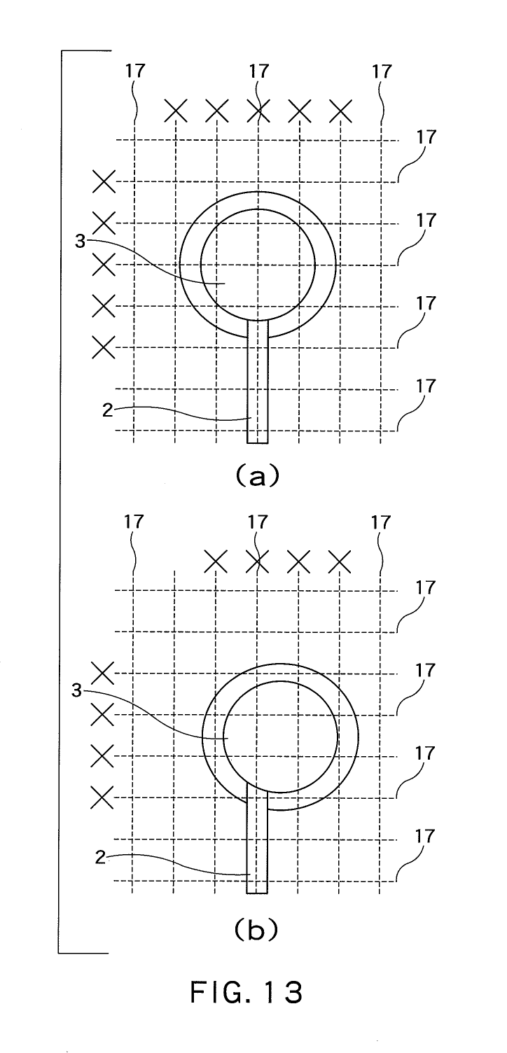

In the first embodiment, the position of the via 3 is determined such that the number of DRC errors 13 generated by allocating the new via 3 becomes the minimum. In a second embodiment of the invention, as illustrated in FIG. 13 (a), a position where the number of wiring tracks 17 through which the wiring lines 2 cannot pass by allocating the new via 3 (obstructed by the via 3) becomes the minimum in the wiring tracks 17 is determined as the position of the via 3. As used herein, the wiring tracks 17 mean the grids 7 on which the wiring lines 2 are not allocated yet but possibly allocated aftertime.

Specifically, for example, when the via 3 is allocated as illustrated in FIG. 13 (a), the number of wiring tracks 17 (the sum of unallocatable wiring lines) through which the wiring lines 2 cannot pass due to the via 3 becomes a total of 10 including the vertical direction and the horizontal direction (X-direction and Y-direction). On the other hand, when the via 3 is allocated as illustrated in FIG. 13 (b), the number of wiring tracks 17 through which the wiring lines 2 cannot pass due to the via 3 becomes a total of 8 including the vertical direction and the horizontal direction. In the second embodiment, the position where the number of wiring tracks 17 through which the wiring lines 2 cannot pass become minimum is determined as the position of the via 3 as illustrated in FIG. 13 (b).

In the second embodiment, it is also assumed that the maze method is used as the wiring design method. In the second embodiment, the wiring design method is not limited to the maze method, but another method may be used as the wiring design method. In the second embodiment, the wiring is performed on the wiring board of the semiconductor package such as the BGA package. However, in the second embodiment, the wiring board that becomes the design target is not limited to the wiring board of the semiconductor package.

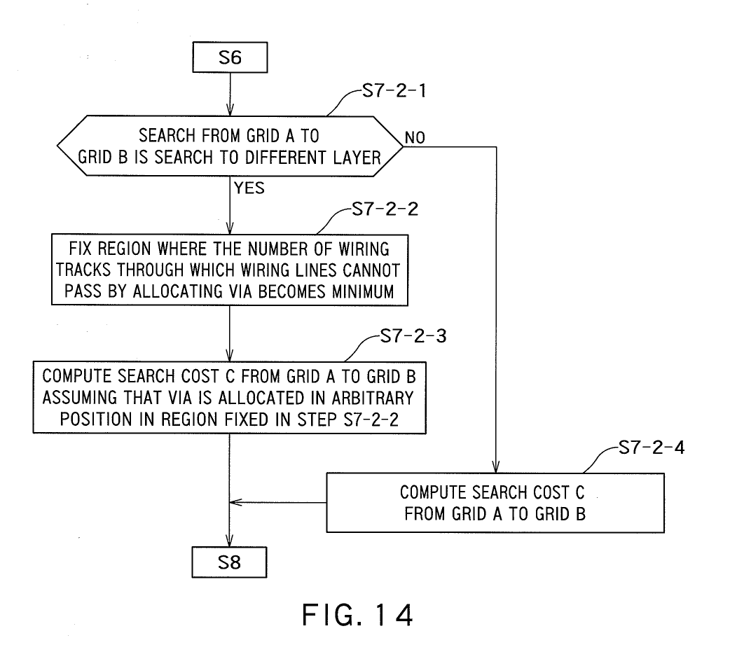

A flowchart of the wiring method of the second embodiment is similar to that of FIG. 4, and Step S7 in the flowchart of FIG. 4 is replaced with a flowchart of FIG. 14.

The flowchart of FIG. 14 unique to the second embodiment will be described in detail. In the second embodiment, the following steps are performed after Step S6 of FIG. 4.

(Step 7-2-1) A determination whether the search from the grid A to the grid B is the search to the different wiring layer is made.

(Step 7-2-2) The region where the number of wiring tracks through which the wiring lines cannot pass by allocating the new via becomes the minimum is fixed.

(Step 7-2-3) Assuming that the via is allocated in an arbitrary position in the region fixed in Step 7-2-2, the search cost C from the grid A to the grid B is computed.

(Step 7-2-4) The search cost C from the grid A to the grid B is computed.

Then the flow goes to Step S8.

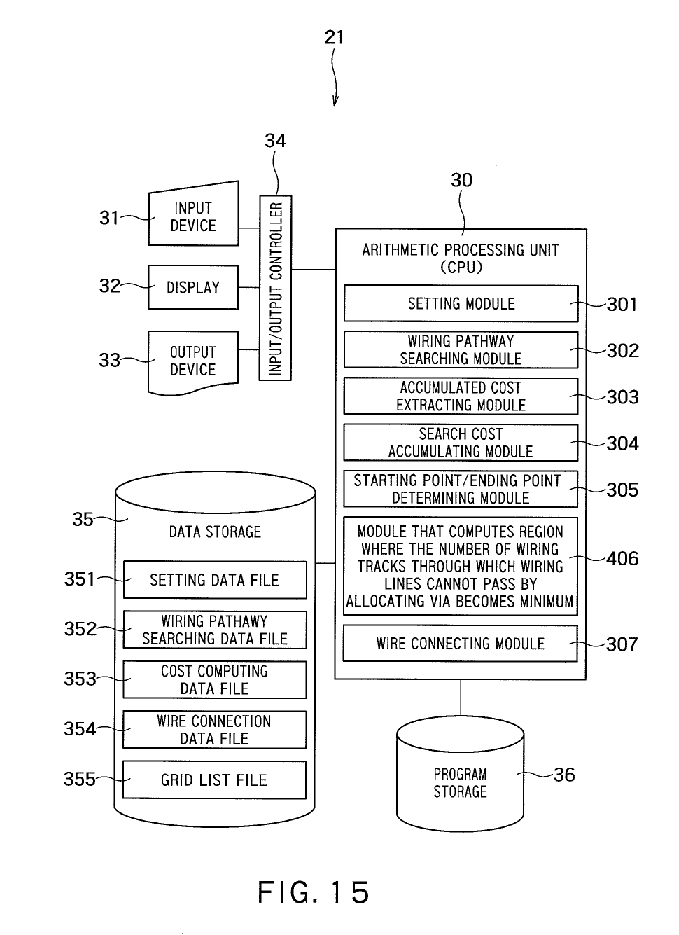

FIG. 15 is a block diagram illustrating a wiring design apparatus 21 of the second embodiment. The block diagram of the wiring design apparatus illustrated in FIG. 15 is substantially identical to that of the wiring design apparatus of the first embodiment illustrated in FIG. 12. Accordingly, only a block unique to the second embodiment illustrated in FIG. 15 will be described in detail. An arithmetic processing unit 30 of the wiring design apparatus 21 of the second embodiment includes a module 406 that computes the region where the number of wiring tracks through which the wiring lines cannot pass by allocating the via becomes the minimum instead of the module 306 that computes the region where the number of DRC errors generated by allocating the via becomes the minimum in the wiring design apparatus of the first embodiment illustrated in FIG. 12. The wiring method is performed with the wiring design apparatus 21 of FIG. 15.

According to the second embodiment, the region where more subsequent wiring lines 2 can be routed is secured on the wiring layer to improve the routability as a whole. Particularly, the routability can be improved when the dimension of the vias 3 is larger than the wiring width of the wiring lines 2. Additionally, the wiring grid interval is set equal to that of the conventional method, so that the design time and the consumption of the computer resource can be suppressed.

In the second embodiment, the wiring method is adopted for the wiring board including the two wiring layers (wiring board upper surface 1a and wiring board lower surface 1b) in which the wiring lines 2 can be allocated. However, some embodiments of the invention is not limited to the two wiring layer, but some embodiments of the invention may be applied to at least three wiring layers. In such cases, in consideration of the plural wiring layers connected to the via 3, the position of the via 3 is determined such that the number of wiring tracks through which the wiring lines 2 cannot pass becomes the minimum therein.

### Third Embodiment

In the second embodiment, the position of the via 3 is determined such that the number of wiring tracks through which the wiring lines 2 cannot pass by allocating the new via 3 becomes the minimum. In a third embodiment of the invention, the position of the via 3 is determined in consideration of a direction in which the wiring is preferentially performed.

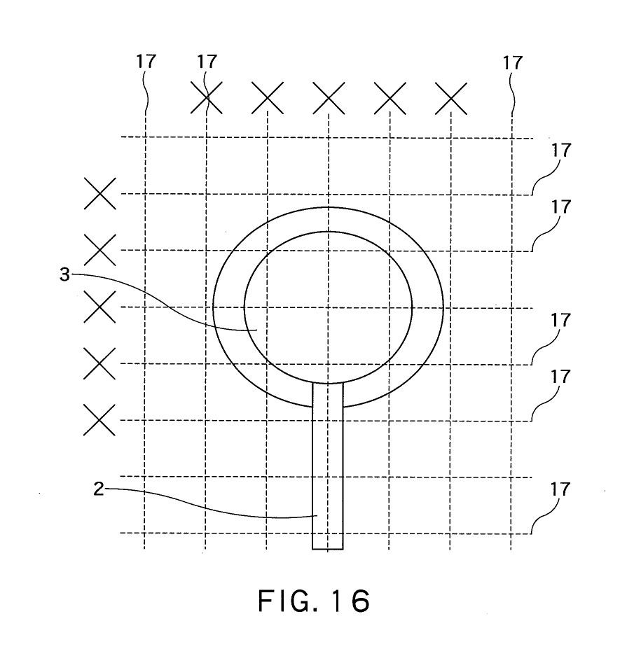

Specifically, in an example illustrated in FIG. 16, the number of wiring tracks 17 through which the wiring lines 2 cannot pass by allocating the new via 3 is computed. The number of wiring tracks 17 (the number of unallocatable horizontal wiring lines) through which the wiring lines 2 cannot pass by allocating the via 3 is 5 in the X-direction, and the number of wiring tracks 17 (the number of unallocatable vertical wiring lines) through which the wiring lines 2 cannot pass by allocating the via 3 is 5 in the Y-direction. For example, the Y-direction (vertical direction) is set to the preferential wiring direction with respect to the X-direction (horizontal direction), and the Y-direction that is of the preferential wiring direction is weighted by 0.8 with respect to the computed number of wiring tracks 17, and the X-direction that is of the non-preferred wiring direction is weighted by 0.2. Accordingly, an index for determining the position of the via 3 is computed as 5×0.8+5×0.2=5. The position of the via 3 is determined such that the computed index becomes the minimum. For example, the index that reflects the number of wiring tracks only in the preferential wiring direction is computed, when the preferential wiring direction is weighted by 1 while the non-preferred wiring direction is weighted by 0.

In the third embodiment, it is also assumed that the maze method is used as the wiring design method. In some embodiments of the invention, the wiring design method is not limited to the maze method, but another method may be used as the wiring design method. In the third embodiment, the wiring is performed on the wiring board of the semiconductor package such as the BGA package. However, in some embodiments of the invention, the wiring board that becomes the design target is not limited to the wiring board of the semiconductor package.

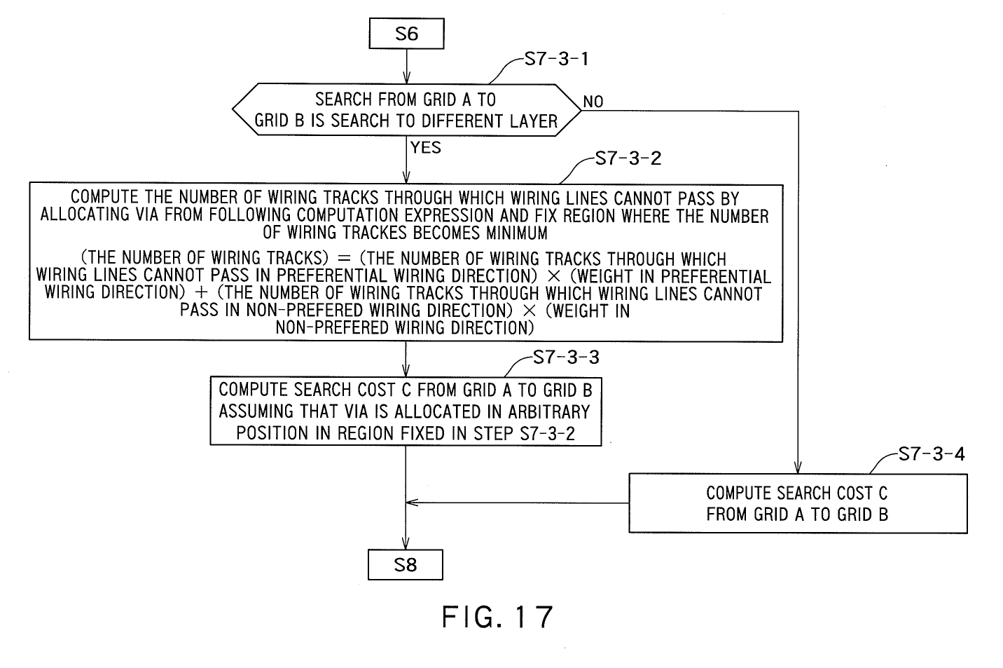

A flowchart of the wiring method of the third embodiment is similar to that of FIG. 4, and Step S7 in the flowchart of FIG. 4 is replaced with a flowchart of FIG. 17.

The flowchart of FIG. 17 unique to the third embodiment will be described in detail. In the third embodiment, the following steps are performed after Step S6 of FIG. 4.

(Step 7-3-1) A determination whether the search from the grid A to the grid B is the search to the different wiring layer is made.

(Step 7-3-2) The index of the number of wiring tracks through which the wiring lines cannot pass by allocating the via is computed from the following computation expression, and the region where the index becomes the minimum is computed.

(index of the number of wiring tracks)=(the number of wiring tracks through which wiring lines cannot pass in preferential wiring direction)×(weight in preferential wiring direction)+(the number of wiring tracks through which wiring lines cannot pass in non-preferred wiring direction)×(weight in non-preferred wiring direction)

(Step 7-3-3) Assuming that the via is allocated in an arbitrary position in the region fixed in Step 7-3-2, the search cost C from the grid A to the grid B is computed.

(Step 7-3-4) The search cost C from the grid A to the grid B is computed.

Then the flow goes to Step S8.

Because the block diagram of the wiring design apparatus of the third embodiment is identical to that of the wiring design apparatus of the second embodiment illustrated in FIG. 15, the description is not repeated here. The wiring method is performed with the wiring design apparatus 21 of FIG. 15.

According to the third embodiment, because the wiring lines 2 are allocated in the preferential wiring direction, the number of wiring tracks is practically computed. Therefore, the region where more subsequent wiring lines 2 can be routed is secured on the wiring layer to improve the routability as a whole. Particularly, the routability can be improved when the dimension of the vias 3 is larger than the wiring width of the wiring lines 2. Additionally, the wiring grid interval is set equal to that of the conventional method, so that the design time and the consumption of the computer resource can be suppressed.

In the third embodiment, the wiring method is adopted for the wiring board including the two wiring layers (wiring board upper surface 1a and wiring board lower surface 1b) in which the wiring lines 2 can be allocated. However, some embodiments of the invention is not limited to the two wiring layer, but some embodiments of the invention may be applied to at least three wiring layers. In such cases, in consideration of the plural wiring layers connected to the via 3, the position of the via 3 is determined such that the number of wiring tracks through which the wiring lines 2 cannot pass becomes the minimum therein.

### Fourth Embodiment

In a fourth embodiment of the invention, similarly to the first embodiment, the region where the number of DRC errors generated by allocating the new via 3 becomes the minimum is computed in determining the position of the via 3. Additionally, similarly to the second embodiment, a position where the number of wiring tracks through which the wiring lines 2 cannot pass by allocating the new via 3 becomes the minimum is computed from the region, thereby determining the final via position. That is, the fourth embodiment is a combination of the first embodiment and the second embodiment, and the fourth embodiment has both the effects of the first and the second embodiments.

In the fourth embodiment, it is also assumed that the maze method is used as the wiring design method. In some embodiments of the invention, the wiring design method is not limited to the maze method, but another method may be used as the wiring design method. In the fourth embodiment, the wiring is performed on the wiring board of the semiconductor package such as the BGA package. However, in some embodiments of the invention, the wiring board that becomes the design target is not limited to the wiring board of the semiconductor package.

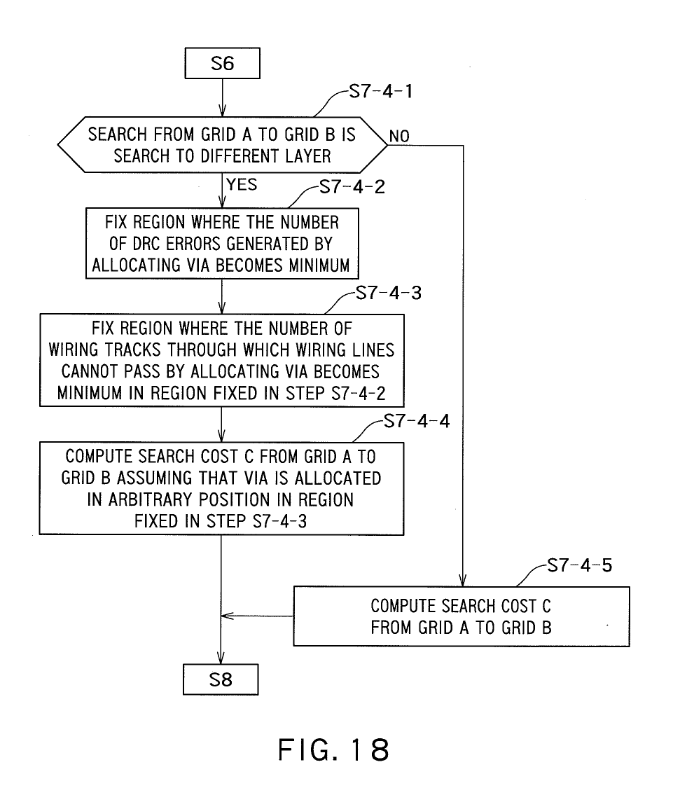

A flowchart of the wiring method of the fourth embodiment is similar to that of FIG. 4, and Step S7 in the flowchart of FIG. 4 is replaced with a flowchart of FIG. 18.

The flowchart of FIG. 18 unique to the fourth embodiment will be described in detail. In the fourth embodiment, the following steps are performed after Step S6 of FIG. 4.

(Step 7-4-1) A determination whether the search from the grid A to the grid B is the search to the different wiring layer is made.

(Step 7-4-2) The region where the number of DRC errors generated by allocating via becomes the minimum is fixed.

(Step 7-4-3) The region where the number of wiring tracks through which the wiring lines cannot pass by allocating the new via becomes the minimum is fixed in the region fixed in Step 7-4-2.

(Step 7-4-4) Assuming that the via is allocated in an arbitrary position in the region fixed in Step 7-4-3, the search cost C from the grid A to the grid B is computed.

(Step 7-4-5) The search cost C from the grid A to the grid B is computed.

Then the flow goes to Step S8.

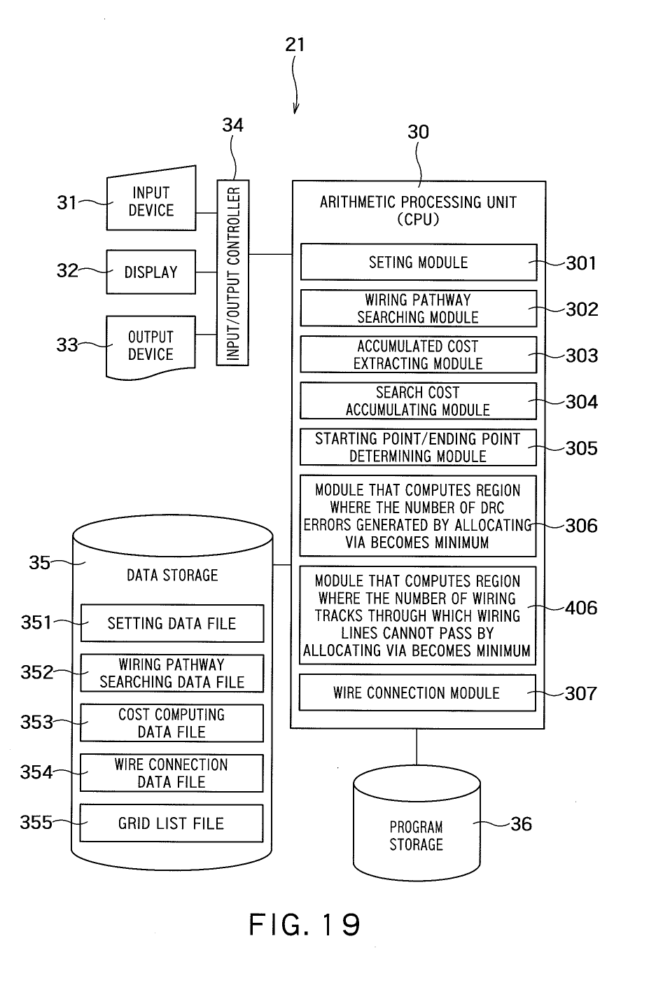

FIG. 19 is a block diagram illustrating a wiring design apparatus 21 of the fourth embodiment. The block diagram of the wiring design apparatus illustrated in FIG. 19 is substantially identical to that of the wiring design apparatus of the first embodiment illustrated in FIG. 12. Accordingly, only a block unique to the fourth embodiment illustrated in FIG. 19 will be described in detail. An arithmetic processing unit 30 of the wiring design apparatus 21 of the fourth embodiment further includes a module 406 that computes the region where the number of wiring tracks through which the wiring lines cannot pass by allocating the via becomes the minimum. The wiring method is performed with the wiring design apparatus 21 of FIG. 19.

According to the fourth embodiment, because the via 3 can be allocated in the optimum position without restricting to the position of the grids 7, the region where more subsequent wiring lines 2 can be routed is secured on the wiring layer to improve the routability as a whole. Particularly, the routability can be improved when the dimension of the vias 3 is larger than the wiring width of the wiring lines 2. Additionally, the wiring grid interval is set equal to that of the conventional method, so that the design time and the consumption of the computer resource can be suppressed.

In the fourth embodiment, the wiring method is adopted for the wiring board including the two wiring layers (wiring board upper surface 1a and wiring board lower surface 1b) in which the wiring lines 2 can be allocated. However, some embodiments of the invention is not limited to the two wiring layer, but some embodiments of the invention may be applied to at least three wiring layers. In such cases, the position of the via 3 is determined in consideration of the plural wiring layers connected to the via 3.

### Fifth Embodiment

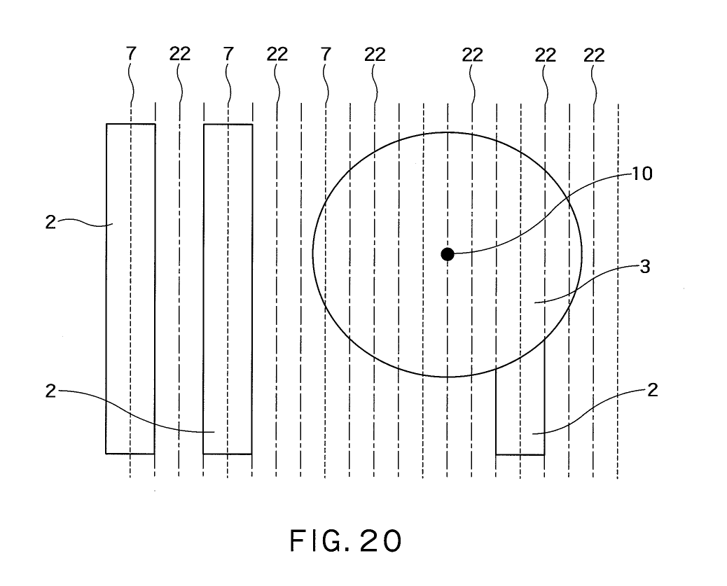

In the fifth embodiment, as illustrated in FIG. 20, via grids 22 for the vias 3, which is different from the grids 7 for the wiring lines 2, are virtually formed on the wiring board 1. The via grids 22 have the interval smaller than that of the grids 7 for the wiring lines 2, and the via 3 is allocated such that the center point 10 of the via 3 is located on the via grid 22. Additionally, in the fifth embodiment, the position of the via 3 is determined such that the number of DRC errors 13 generated by allocating the via 3 becomes the minimum. That is, the fifth embodiment is a combination of the first embodiment and utilization of the via grids 22, and the fifth embodiment has both the effect obtained by the first embodiment and the effect obtained by utilizing the via grids 22.

In the fifth embodiment, it is also assumed that the maze method is used as the wiring design method. In some embodiments of the invention, the wiring design method is not limited to the maze method, but another method may be used as the wiring design method. In the fifth embodiment, the wiring is performed on the wiring board of the semiconductor package such as the BGA package. However, in some embodiments of the invention, the wiring board that becomes the design target is not limited to the wiring board of the semiconductor package.

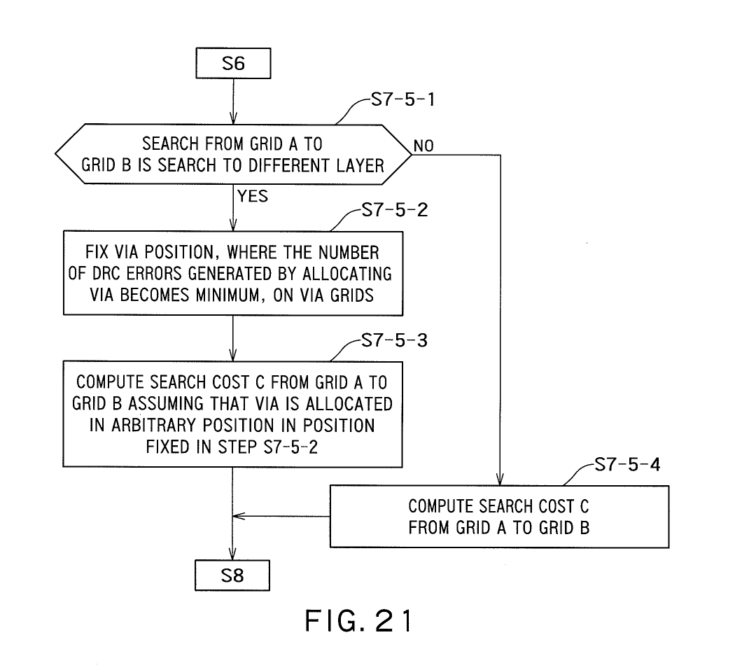

A flowchart of the wiring method of the fifth embodiment is similar to that of FIG. 4, and Step S7 in the flowchart of FIG. 4 is replaced with a flowchart of FIG. 21.

The flowchart of FIG. 21 unique to the fifth embodiment will be described in detail. In the fifth embodiment, the following steps are performed after Step S6 of FIG. 4.

(Step 7-5-1) A determination whether the search from the grid A to the grid B is the search to the different wiring layer is made.

(Step 7-5-2) The via position where the number of DRC errors generated by allocating the via becomes the minimum is fixed on the via grids.

(Step 7-5-3) Assuming that the via is allocated in the position fixed in Step 7-5-2, the search cost C from the grid A to the grid B is computed.

(Step 7-5-4) The search cost C from the grid A to the grid B is computed.

Then the flow goes to Step S8.

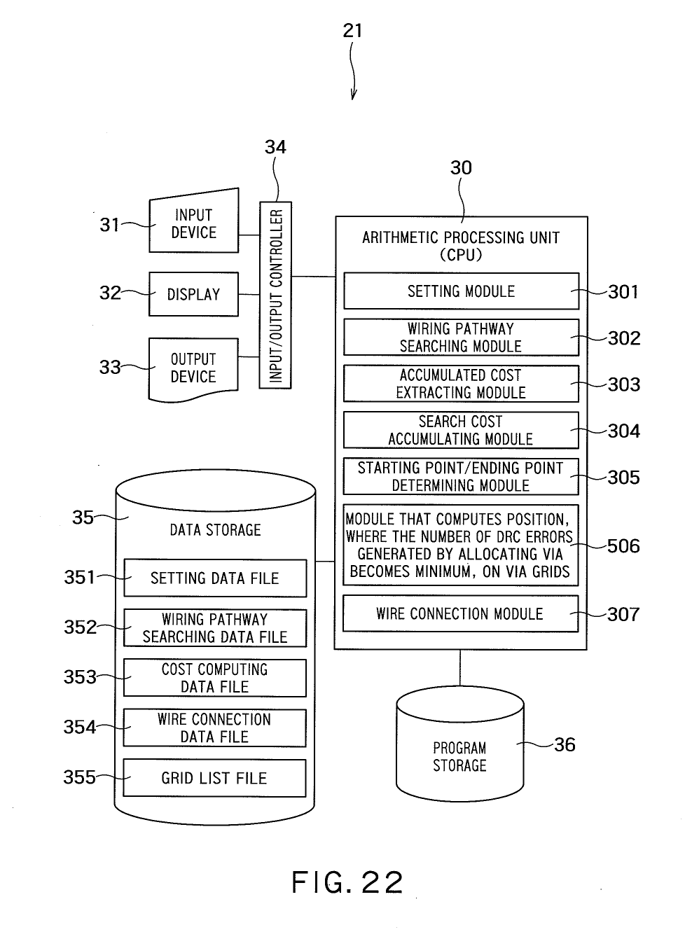

FIG. 22 is a block diagram illustrating a wiring design apparatus 21 of the fifth embodiment. The block diagram of the wiring design apparatus illustrated in FIG. 22 is substantially identical to that of the wiring design apparatus of the first embodiment illustrated in FIG. 12. Accordingly, only a block unique to the fifth embodiment illustrated in FIG. 22 will be described in detail. An arithmetic processing unit 30 of the wiring design apparatus 21 of the fifth embodiment includes a module 506 that computes the position on the via grids 22, where the number of DRC errors generated by allocating the via becomes the minimum instead of the module 306 that computes the region where the number of DRC errors generated by allocating the via becomes the minimum in the wiring design apparatus of the first embodiment illustrated in FIG. 12. The wiring method is performed with the wiring design apparatus 21 of FIG. 22.

According to the fifth embodiment, because the wiring pathway is determined based on the wiring grids 7, the processing time and the necessary memory capacity are not dramatically increased. Additionally, because the via 3 is allocated on the via grids 22 having the interval finer than the wiring grid interval, the region where more wiring lines can be routed compared with the conventional method is secured on the wiring layer, and the routability can be improved.

In the fifth embodiment, the wiring method is adopted for the wiring board including the two wiring layers (wiring board upper surface 1a and wiring board lower surface 1b) in which the wiring lines 2 can be allocated. However, some embodiments of the invention is not limited to the two wiring layer, but some embodiments of the invention may be applied to at least three wiring layers. In such cases, in consideration of the plural wiring layers connected to the via 3, the position of the via is determined such that the number of DRC errors becomes the minimum therein.

The wiring design methods of the embodiments can be implemented by software. When the wiring design method is implemented by the software, a program that implements at least part of the wiring design method is stored in a recording medium such as a flexible disk and a CD-ROM, and a computer may read and execute the program. The recording medium is not limited to a detachable recording medium such as a magnetic disk and an optical disk, but a fixed recording medium such as a hard disk drive and a memory may be used.

The program that implements at least part of the wiring design method may be distributed through a communication line (including wireless communication) such as the Internet. The program may be distributed through a wire line such as the Internet or a wireless line while encrypted, modulated, or compressed. Alternatively, the program stored in the recording medium may be distributed while encrypted, modulated, or compressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A method for determining a wiring pathway comprising:
providing a first wiring layer and a second wiring layer on a wiring board;
assigning a first grid to the first wiring layer, the first grid comprising
a plurality of first horizontal lines,
a plurality of first vertical lines, and
a plurality of first intersections between the plurality of first horizontal lines and the plurality of first vertical lines;
providing a first wiring line based on the shape of the first grid, and assigning the first wiring line to the first wiring layer;
assigning a second grid to the second wiring layer, the second grid comprising
a plurality of second horizontal lines,
a plurality of second vertical lines, and
a plurality of second intersections between the plurality of second horizontal lines and the plurality of second vertical lines;
providing a second wiring line based on the shape of the second grid, and assigning the second wiring line to the second wiring layer;
providing a via between the first wiring line and the second wiring line, and assigning the via to the first wiring layer and the second wiring layer;
providing a third wiring line configured to allow for electric conduction between the first wiring line and the second wiring line through the via, and assigning the third wiring line to the first wiring layer and the second wiring layer; and
determining a pathway of an additional wiring line configured to allow for electric conduction from the first grid to the second grid, the pathway having a width based on a pathway cost corresponding to the pathway, wherein determining the pathway of the additional wiring line comprises
determining a starting point on the first grid and an ending point on the second grid,
selecting an intersection from the plurality of first intersections,
determining a first path for the additional wiring line from the starting point to the selected intersection,
determining a first via-allocatable region within the first wiring layer and a second via-allocatable region within the second wiring layer based on positions of the third wiring line and the via,
proximal the selected intersection, providing an additional via between the first wiring layer and the second wiring layer, such that the additional via is configured to be disposed between the first via-allocatable region and the second via-allocatable region,
selecting a position for the additional via such that a lower surface of the additional via is included in the first via-allocatable region, an upper surface of the additional via is included in the second via-allocatable region, and the selected intersection is included in an arbitrary position in a region of the lower surface, and
determining a second path for the additional wiring line from the additional via to the ending point, such that the first path, the additional via, and the second path define the pathway of the additional wiring line.

2. The method according to claim 1, wherein
the first via-allocatable region is selected to minimize the number of design rule violations in which the position of the additional via on the first wiring layer is in a region in which the first wiring line and the via are allocated, and
the second via-allocatable region is selected to minimize the number of design rule violations in which the position of the additional via on the second wiring layer is in a region in which the second wiring line and the via are allocated.

3. The method according to claim 1, wherein the plurality of first horizontal lines and the plurality of first vertical lines are orthogonal, and the plurality of second horizontal lines and the plurality of second vertical lines are orthogonal.

4. The method according to claim 1, wherein the upper surface and the lower surface of the additional via have a circular shape, and diameters of the upper surface and the lower surface are larger than a width of the additional wiring line.

5. The method according to claim 1, wherein the upper surface and the lower surface of the additional via have a rectangular shape, and at least one of the rectangle sides is larger than a width of the additional wiring line.

6. A method for determining a wiring pathway comprising:
providing a first wiring layer and a second wiring layer on a wiring board;
assigning a first grid to the first wiring layer, the first grid comprising
a plurality of first horizontal lines,
a plurality of first vertical lines, and
a plurality of first intersections between the plurality of first horizontal lines and the plurality of first vertical lines;
providing a first wiring line based on the shape of the first grid, and assigning the first wiring line to the first wiring layer;
assigning a second grid to the second wiring layer, the second grid comprising
a plurality of second horizontal lines,
a plurality of second vertical lines, and
a plurality of second intersections between the plurality of second horizontal lines and the plurality of second vertical lines;
providing a second wiring line based on the shape of the second grid, and assigning the second wiring line to the second wiring layer;
providing a via between the first wiring line and the second wiring line, and assigning the via to the first wiring layer and the second wiring layer;
providing a third wiring line configured to allow for electric conduction between the first wiring line and the second wiring line through the via, and assigning the third wiring line to the first wiring layer and the second wiring layer; and
determining a pathway of an additional wiring line configured to allow for electric condition from the first grid to the second grid, the pathway having a width based on a pathway cost corresponding to the pathway, wherein determining the pathway of the additional wiring line comprises
determining a starting point on the first grid and an ending point on the second grid,
selecting an intersection from the plurality of first intersections,
determining a first path for the additional wiring line from the starting point to the selected intersection,
selecting a plurality of working positions for an additional via, such that the selected intersection is included in an arbitrary position in a region of additional via's lower surface,
for each of the working positions, determining the number first horizontal lines and first vertical lines in the first wiring layer that are unallocatable because the lines are obstructed by a lower surface of the additional via corresponding to that working position,
for each of the working positions, determining the number of second horizontal lines and second vertical lines in the second wiring layer that are unallocatable because the lines are obstructed by an upper surface of the additional via corresponding to that working position,
for each of the working positions, determining the total number of unallocatable wiring lines by adding the number of first unallocatable horizontal wiring lines, the number of first unallocatable vertical wiring lines, the number of second unallocatable horizontal wiring line, and the number of second unallocatable vertical wiring lines,
selecting the working position corresponding to the lowest total number of unallocatable wiring lines, and
determining a second path for the additional wiring line to the ending point from the additional via allocated in the selected working position, such that the first path, the additional via allocated in the selected working position, and the second path define the pathway of the additional wiring line.

7. The method according to claim 6, wherein the plurality of first horizontal lines and the plurality of first vertical lines are orthogonal, and the plurality of second horizontal lines and the plurality of second vertical lines are orthogonal.

8. The method according to claim 6, wherein the upper surface and the lower surface of the additional via have a circular shape, and diameters of the upper surface and the lower surface are larger than a width of the additional wiring line.

9. The method according to claim 6, wherein the upper surface and the lower surface of the additional via have a rectangular shape, and at least one of the rectangle sides is larger than a width of the additional wiring line.

10. The method according to claim 6, further comprising associating a numerical weight with one or more of the number of first unallocatable horizontal wiring lines, the number of first unallocatable vertical wiring lines, the number of second unallocatable horizontal wiring line, and the number of second unallocatable vertical wiring lines before determining the total number of unallocatable wiring lines.

11. The method according to claim 10, wherein the plurality of first horizontal lines and the plurality of first vertical lines are orthogonal, and the plurality of second horizontal lines and the plurality of second vertical lines are orthogonal.

12. The method according to claim 10, wherein the upper surface and the lower surface of the additional via have a circular shape, and diameters of the upper surface and the lower surface are larger than a width of the additional wiring line.

13. The method according to claim 10, wherein the upper surface and the lower surface of the additional via have a rectangular shape, and at least one of the rectangle sides is longer than a width of the additional wiring line.

14. A method for determining a wiring pathway comprising:
providing a first wiring layer and a second wiring layer on a wiring board;
assigning a first grid to the first wiring layer, the first grid comprising
a plurality of first horizontal lines,
a plurality of first vertical lines, and
a plurality of first intersections between the plurality of first horizontal lines and the plurality of first vertical lines;
providing a first wiring line based on the shape of the first grid, and assigning the first wiring line to the first wiring grid;
assigning a second grid to the second wiring layer, the second grid comprising
a plurality of second horizontal lines,
a plurality of second vertical lines, and
a plurality of second intersections between the plurality of second horizontal lines and the plurality of second vertical lines;
providing a second wiring line based on the shape of the second grid, and assigning the second wiring line to the second wiring layer;
providing a via between the first wiring line and the second wiring line, and assigning the via to the first wiring layer and the second wiring layer;
providing a third wiring line configured to allow for electric conduction between the first wiring line and the second wiring line through the assigned via, and assigning the third wiring line to the first wiring layer to the second wiring layer;
determining a pathway of an additional wiring line configured to allow for electric conduction from the first grid to the second grid, the pathway having a width based on a pathway cost corresponding to the pathway, wherein determining the pathway of the additional wiring line comprises
determining a starting point on the first grid and an ending point on the second grid,
selecting an intersection from the plurality of first intersections,
determining a first path for the additional wiring line from the starting point to the selected intersection,
determining a first via-allocatable region within the first wiring layer and a second via-allocatable region within the second wiring layer based on positions of the third wiring line and the assigned via,
selecting a plurality of working positions for an additional via, such that the selected intersection is included in an arbitrary position in a region of the additional via's lower surface, the additional via's lower surface is included in the first via-allocatable region, and the additional via's upper surface is included in the second via-allocatable region,
for each of the working positions, determining the number of first horizontal lines and the number of first vertical lines in the first wiring layer that are unallocatable because the lines are obstructed by the lower surface of the additional via corresponding with that working position,
for each of the working positions, determining the number of second horizontal lines and the number of second vertical lines in the second wiring layer that are unallocatable because the lines are obstructed by the upper surface of the additional via corresponding with that working position,
for each of the working positions, determining the total number of unallocatable wiring lines by adding the number of first unallocatable horizontal wiring lines, the number of first unallocatable vertical wiring lines, the number of second unallocatable horizontal wiring lines, and the number of second unallocatable vertical wiring lines;
selecting the working position corresponding to the lowest total number of unallocatable wiring lines; and
determining a second path for the additional wiring line from the additional via corresponding with the selected working position to the ending point, such that the first path, the additional via corresponding with the selected working position, and the second path define the pathway of the additional wiring line.

15. The method according to claim 14, wherein
the first via-allocatable region is selected to minimize the number of design rule violations in which the position of the additional via corresponding to the selected working position on the first wiring layer is in a region in which the first wiring line and the assigned via are allocated, and
the second via-allocatable region is selected to minimize the number of design rule violations in which the position of the additional via corresponding to the selected working position on the second wiring layer is in a region in which the second wiring line and the assigned via are allocated.

16. The method according to claim 14, wherein the plurality of first horizontal lines and the plurality of first vertical lines are orthogonal, and the plurality of second horizontal lines and the plurality of second vertical lines are orthogonal.

17. The method according to claim 14, wherein the upper surface and the lower surface of the additional via have a circular shape, and diameters of the upper surface and the lower surface are larger than a width of the additional wiring line.

18. The method according to claim 14, wherein the upper surface and the lower surface of the additional via have a rectangular shape, and at least one of the rectangle sides is longer than a width of the additional wiring line.

19. The method according to claim 14, further comprising associating a numerical weight with one or more of the number of first unallocatable horizontal wiring lines, the number of first unallocatable vertical wiring lines, the number of second unallocatable horizontal wiring line, and the number of second unallocatable vertical wiring lines before determining the total number of unallocatable wiring lines.
